(19) United States
(12) Patent Application Publication
(10) Pub. No.: US 2003/0029034 A1
(43) Pub. Date: Feb. 13, 2003

(54) Method of removing and replacing defective piece of printed circuit board formed on a panel

(75) Inventor: Cheng-Hsien Chou, Tu-Cheng City (TW)

Correspondence Address: DOUGHERTY & TROXELL, SUITE 1404, 5205 LEESBURG PIKE, FALLS CHURCH, VA, 22041, US

(73) Assignee: Unitech Printed Circuit Board Corp.

(21) Appl. No.: 09/923,452

(22) Filed: Aug. 8, 2001

(51) Int. Cl. H05K 3/36; B23P 17/00

(52) U.S. Cl. 29/840; 29/830; 29/413

(57) ABSTRACT

A method of removing and replacing a defective piece of printed circuit board formed on a panel, including the steps of using a router to form a breaking aperture at each connecting joint around a good piece on an unqualified panel, so that a connecting edge about 50 μm long is left at each end of the breaking aperture, and breaking the connecting edges through one punch to remove the good piece from the panel; using the same way to remove a bad piece from a qualified panel to produce a void having size and shape identical to those of the removed good piece; positioning the removed good piece into the void; and filling the reconnected breaking aperture with bonding agent to securely connect the substitute good piece to the panel, allowing subsequent printing of solder layer and insertion of surface mounting devices to be smoothly completed on the panel.

### BACKGROUND OF THE INVENTION

The present invention relates to a method of removing and replacing defective piece of printed circuit board formed on a panel, and more particularly to a method of removing and replacing defective piece of printed circuit board formed on a panel in which a router is used to form a breaking aperture at each connecting joint around a good circuit board piece on an unqualified panel and a defective circuit board piece on a qualified panel, so that each of these good and defective pieces could be easily removed from the panels by breaking the connecting joints at the breaking apertures with one single punch, and the removed good pieces could replace the defective ones by positioning them into voids formed by the removed defective pieces on the qualified panel and filling bonding agent in the breaking apertures to firmly bond the substitute good pieces to the panel.

Among the currently available ways of manufacturing various kinds of circuit boards, it is a common practice to arrange a plurality of circuit board pieces on one panel, depending on the size of individual circuit boards to be manufactured or the requirements in manufacturing process. Since the size varies with different types of circuit boards, the arrangement of these circuit board pieces on the panel varies, too. FIG. 1 shows a panel 10 including four circuit board pieces 11, and FIG. 6 shows a panel 20 including thirty-five circuit board pieces 21. The arrangement of pieces 11 on the panel 10 is completely different from that of pieces 21 on the panel 20. Moreover, the rate of bad yield of circuit board pieces on each panel varies with client's particular requirement or rules of quality control. For example, only one defective piece 11A is allowed for each panel 10, while three defective pieces 21A are allowed for each panel 20. A panel 10 or 20 having defective piece or pieces in a number below the specified rate of bad yield may still be accepted as a qualified panel for subsequent processing, such as printing of a solder layer or insertion of surface mounting devices. On the contrary, a panel 10 or 20 having defective piece or pieces in a number exceeded the specified rate of bad yield will be considered as an unqualified panel and must be completely discarded. From the standpoint of a circuit board manufacturer, there are still many good circuit board pieces on the unqualified panel that could be utilized as well. Discarding of these usable good circuit board pieces along with other defective ones forms unnecessary waste and increases manufacturing cost of the circuit boards. Taiwan Patent Publication No. 428423 entitled “Method of Recovering and Rebuilding Defective Circuit Board Pieces” discloses a method for collecting good circuit board pieces from an unqualified panel and removing defective circuit board pieces from a qualified panel, and substituting the collected good pieces for the removed defective pieces.

As a matter of fact, the method disclosed in Taiwan Patent Publication No. 428423 is an ordinary skill in the electronic industrial field. For example, some TV game suppliers in Taiwan had tried many years ago to sort out usable integrated circuits (IC's) from scraped circuit boards for TV games or telephones imported from Japan. The electronic manufacturers in Taiwan at that time already had sufficient ability of designing TV games and telephones, but they encountered the problem of shortage of IC's. It seemed to be a good way to utilize these good IC's sorted out from the scraped TV games and telephones by implanting them on new circuit boards having design identical to the scraped ones and thereby providing new TV games and telephones having these reused IC's for sale. Even the IC's developed about more than one decade ago have simpler structure and are not so compact and precise as the currently available ones, the method disclosed in Taiwan Patent Publication No. 428423 for recovering and rebuilding defective circuit boards is not desired for implementation due to the following disadvantages:

1. According to Taiwan Patent Publication No. 428423, defective circuit board pieces are removed from a qualified panel to form voids thereat, and good circuit board pieces are removed from an unqualified panel to fill up the voids on the qualified panel. To do so, tongues and grooves are separately formed on joints of each void and the substitute good circuit board piece, so that the two components are connected together in the manner of rabbeted joint. However, some arrangements of the circuit board pieces on the panels do not provide extra space for forming tongues and grooves at the joints of the voids and the substitute good pieces. That is, the method disclosed in Taiwan Patent Publication No. 428423 is not applicable to all types of arrangements of circuit board pieces on the panel.

2. The tongues and the grooves are formed on the joints of each void and the substitute goodpiece by cutting. The tongues are either loosely or tightly fitted in the grooves. In the case of a tight fit, it is uneasy to connect all the joints in this rabbet manner. And, in the case of a loose fit, the substitute good piece tends to misalign with the void at the rabbeted joints and therefore has adverse influence on the subsequent processing of the panel.

3. It is uneasy to apply bonding agent to any clearance between the tongues and the grooves to ensure firm and stable connection of the substitute good piece to the void. In the case the bonding agent is applied over surfaces of the circuit board, the applied bonding agent must not be too thin in thickness to provide good bonding effect, or be too thick to enable subsequent printing of solder layer. Poor bonding of the substitute good piece to the panel at the void might result in a circuit board piece failing to bear a surface pressure produced at subsequent insertion of surface mounting devices onto the circuit board piece and accordingly undesired separation or displacement of the substitute good piece from the panel.

### SUMMARY OF THE INVENTION

A primary object of the present invention is to provide a method of removing and replacing a defective piece of printed circuit board formed on a panel, in which a router is used to form a breaking aperture at each connecting joint around a circuit board piece to be removed from a panel, so that a connecting edge is provided at each end of the breaking aperture. The circuit board piece could then be removed by breaking all the connecting edges around the piece through one single punch. The broken connecting edges assist in alignment of a substitute good circuit board piece removed from one panel with a void formed on another panel by a removed defective piece. Bonding agent could then be filled in the breaking apertures around the substitute good piece positioned in the void to accurately bond the good piece to the panel.

In this way, a substitute good circuit board piece collected from an unqualified panel could be accurately and stably located on a qualified panel to replace a defective piece, and securely connected to the panel to form an integral unit again.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a top view of a first embodiment of a qualified panel with spaced PCB pieces that can be processed with the method according to the present invention;

FIG. 2 is a top view of a first embodiment of an unqualified panel with spaced PCB pieces that can be processed with the method according to the present invention;

FIG. 3 is a fragmentary and enlarged view of the panel of FIGS. 1 and 2, showing a breaking aperture is formed at a connecting joint on the panel using the method of the present invention;

FIG. 4 is similar to FIG. 3 with the connecting joint being separated apart at the breaking aperture;

FIG. 5 is similar to FIG. 3 with the breaking aperture filled with bonding agent to re-connect the separated connecting joint shown in FIG. 4;

FIG. 6 is a top view of a second embodiment of a qualified panel with adjacent PCB pieces that can be processed with the method according to the present invention;

FIG. 7 is a top view of a second embodiment of an unqualified panel with adjacent PCB pieces that can be processed with the method according to the present invention;

FIG. 8 is a fragmentary and enlarged view of the panel of FIGS. 6 and 7, showing a breaking aperture is formed at a connecting joint on the panel using the method of the present invention;

FIG. 9 is similar to FIG. 8 with the connecting joint being separated apart at the breaking aperture;

FIG. 10 is similar to FIG. 8 with the breaking aperture filled with bonding agent to re-connect the separated connecting joint shown in FIG. 9; and

FIG. 11 is a flowchart showing steps included in the method of the present invention.

### DETAILED DESCRIPTION OF THE PREFERRED EMBODIMENTS

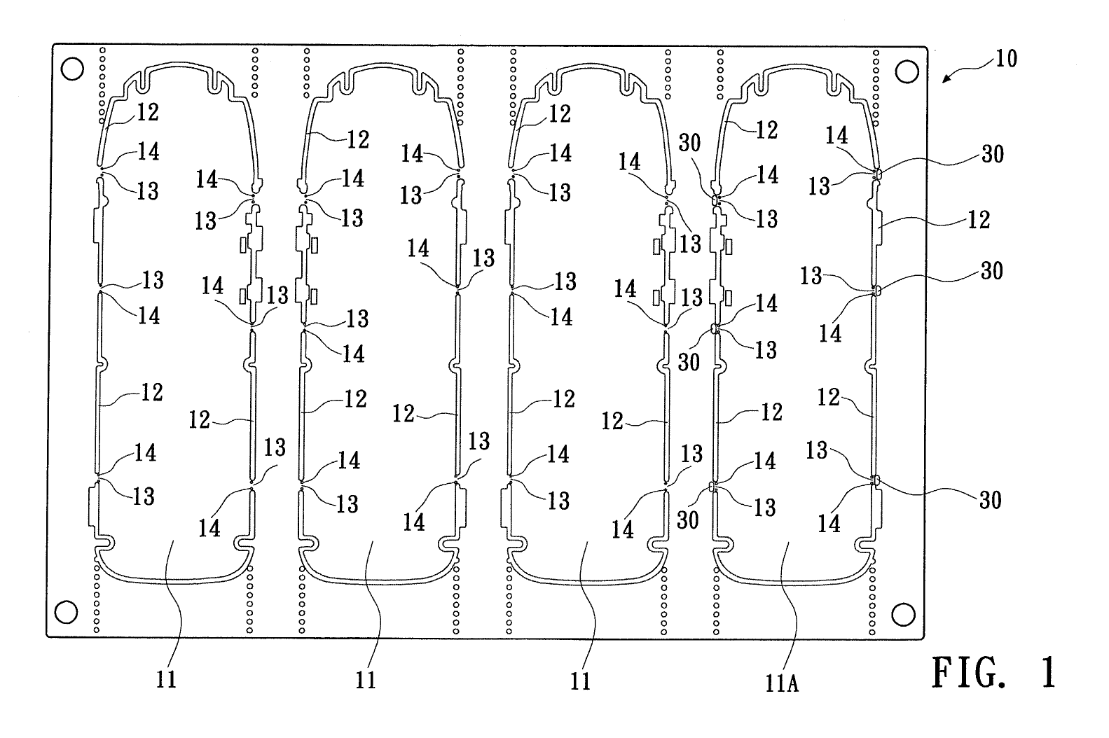

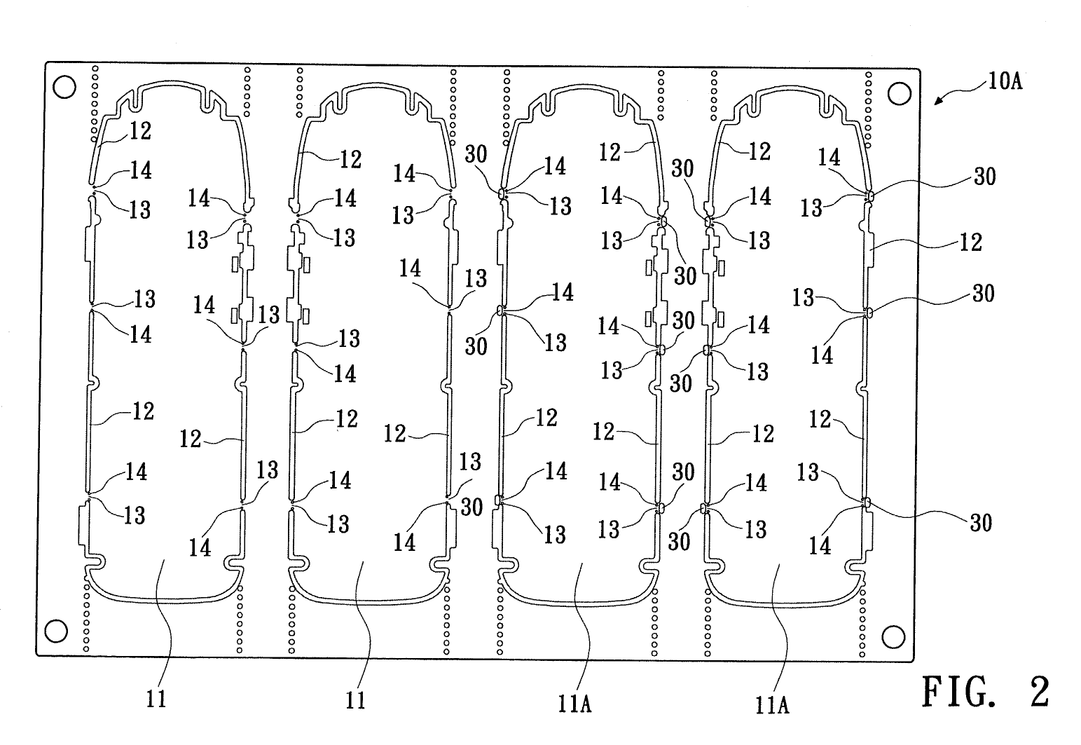

Please refer to FIGS. 1 and 2 that show a first embodiment of a qualified panel 10 and an unqualified panel 10A, respectively, on which a plurality of uniform circuit board pieces 11 are formed. In the illustrated panels 10 and 10A, there are four pieces 11 formed on each of them. Each piece 11 is to be produced into an independent printed circuit board (PCB). Each piece 11 is formed on the panel 10, 10A by cutting a slot 12 on the panel 10, 10A, such that the slot 12 defines a profile for each piece 11 and separates the piece 11 from other portions of the panel 10, 10A. To keep each piece 11 connected to the panel 10, 10A without becoming completely separated from the panel 10, 10A, a plurality of connecting joints 13, that are a part of the panel 10, 10A, are spaced along the slot 12 at predetermined positions to support the piece 11. Each connecting joint 13 is perforated to form a plurality of perforations 14 thereon, and these perforations 14 together form a breaking line to facilitate future punching of the piece 11 out of the panel 10, 10A. In the following description, the qualified panel 10 is defined as a panel being found in a quality check to have only one defective piece 11A among the four pieces 11 formed on the same panel 10; and the unqualified panel 1OA is defined as a panel being found in quality check to have at least two defective pieces 11A among the four pieces 11 formed on the same panel 10.

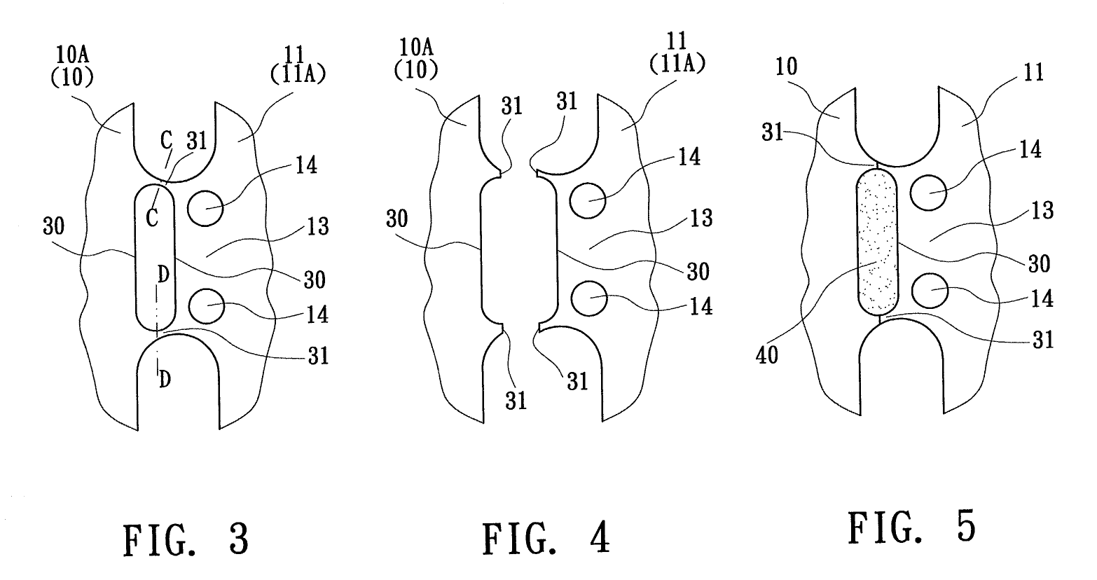

Please refer to FIGS. 3 and 4. To remove a defective piece 11A from a qualified panel 10 or a good piece 11 from an unqualified panel 10A, a router (not shown) is employed to form a breaking aperture 30 on each of the connecting joints 13 spaced along the slot 12 surrounding the piece 11 or 11A. The breaking aperture 30 is formed at a predetermined position on the connecting joint 13 through precision machining and has a predetermined size, so that a part of the connecting joint 13 about 50 μm in length is left at each end of the breaking aperture 30 to provide a connecting edge 31. Later, the good or the defective pieces 11 or 11A may be removed from the unqualified or the qualified panel 10A or 10, respectively, through just one punch to break the connecting edges 31 at all breaking apertures 30, as shown in FIG. 4. The connecting edges 31 may be punched to separate along lines extended in any direction. In FIG. 3, there is shown a normal punching line C—C substantially perpendicular to the connecting edge 31, and another slant punching line D—D that is not perpendicular to the connecting edge 31.

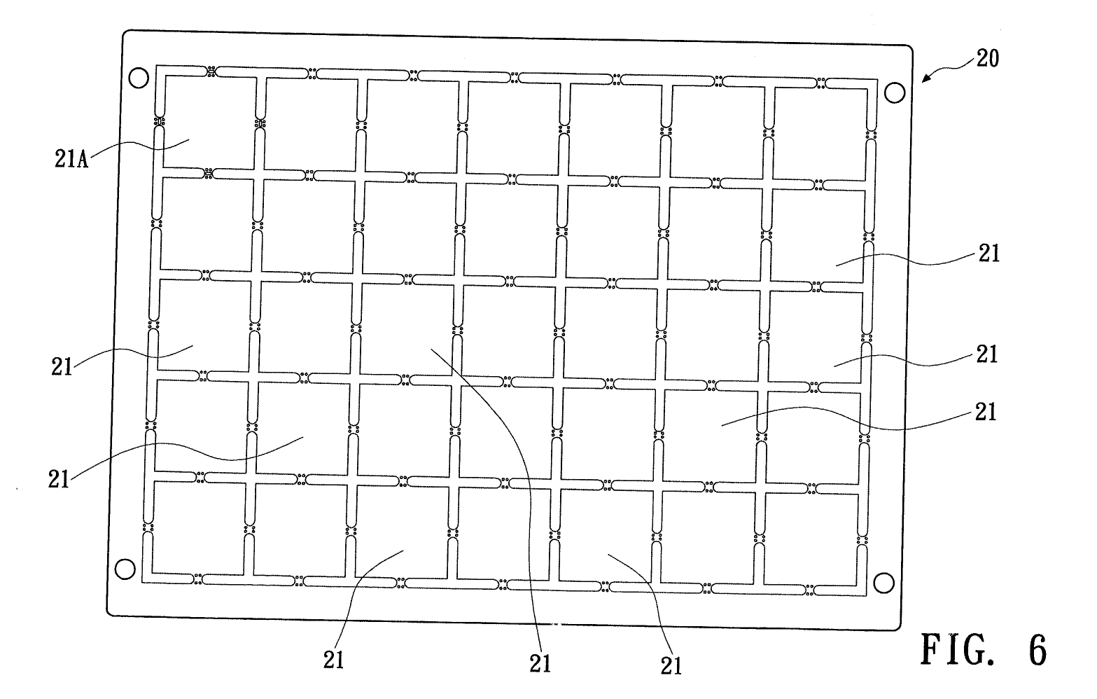

After each defective piece 11A is removed from the qualified panel 10, a void having fixed size and shape is correspondingly formed on the qualified panel 10. The good pieces 11 removed from the unqualified panels 10A one by one have size and shape, including those of the connecting edges 31 at the breaking apertures 30 of all connecting joints 13, almost identical to those of the voids on the qualified panels 10, and could therefore be placed into the voids on the qualified panel 10 to replace the removed defective pieces 11A. By correspondingly aligning the broken connecting edges 31 on the substitute good pieces 10 to that left on each breaking aperture 30 on the panel 10, the substitute good pieces 10 could be accurately located in the voids, as shown in FIG. 5, to resume the breaking apertures 30 on the panel 10 to a shape almost the same as that shown in FIG. 3. Since each breaking aperture 30 has predetermined limited area, it could be easily filled with an adequate amount of a suitable bonding agent 40. Moreover, each breaking aperture 30 has an inner wall surface that provides sufficient contact area between the breaking aperture 30 and the bonding agent 40, it is therefore possible to obtain a good bonding force at the reconnected connecting edges 31 and the resumed breaking aperture 30, and to ensure accurate and stable location and connection of the substitute pieces 11 on and to the panel 10 for smooth completion of subsequent manufacture processes, including printing of solder layer and insertion of surface mounting devices onto the circuit board.

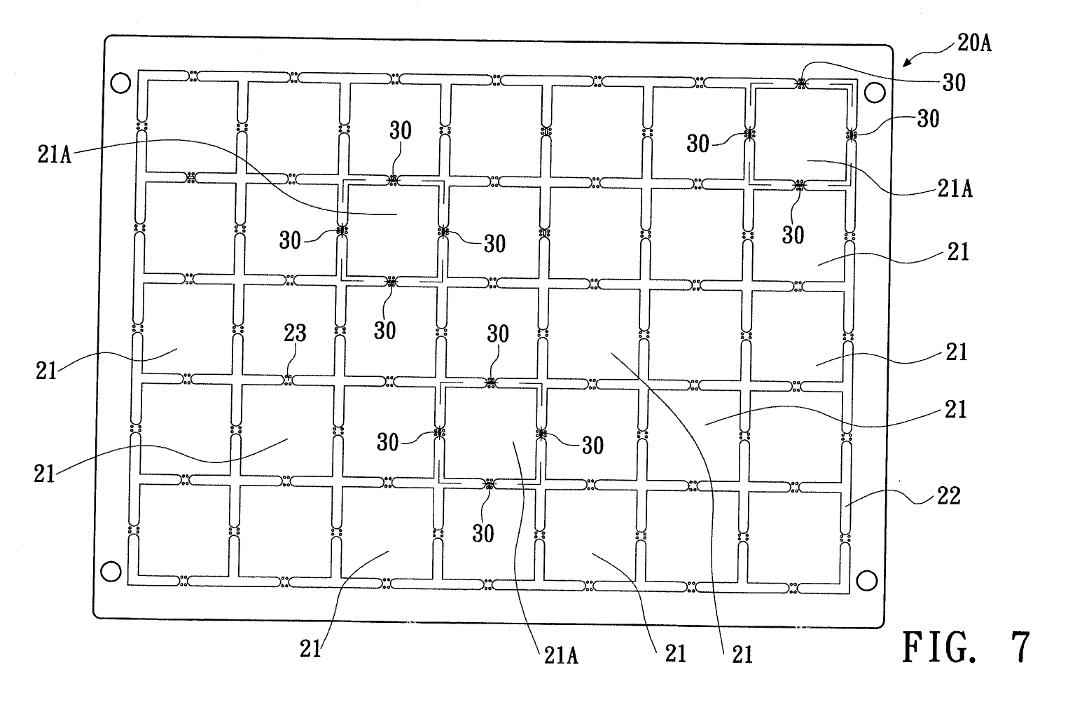

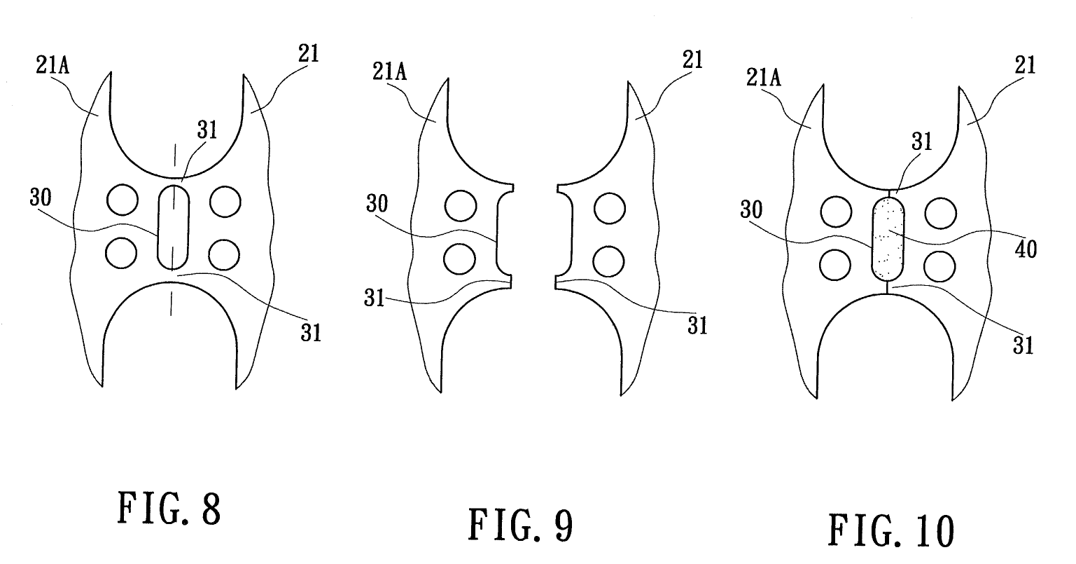

The method of the present invention may be applied to differently shaped and sized printed circuit board pieces. FIGS. 6 and 7 show a qualified panel 20 and an unqualified panel 20A, respectively. Both panels 20 and 20A includes a plurality of good pieces 21 and defective pieces 21A. Each piece 21 or 21A has a slot 22 surrounding it to define a profile thereof and separate the piece 21, 21A from other pieces 21, 21A. However, these pieces 21, 21A are kept connected to one another and to the panel 20, 20A by a plurality of connecting joints 23. The connecting joint 23 is structurally different from the connecting joint 13 on the panel 10, 10A in that the former is directly located between two adjacent pieces 21 while the latter is located between the piece 11 and the panel 10. In the case of panel 20, 20A and connecting joint 23, there is only very limited physical area at each connecting joint 23. It is therefore impossible to form tongues and grooves at the connecting joints 23 as suggested in Taiwan Patent Publication No. 428423 to reconnect the substitute good pieces to voids of removed defective pieces on the qualified panels. However, the method of the present invention employing breaking apertures 30, connecting edges 31 and bonding agent 40 is still applicable to the connecting joints 23 on panels 20, 20A, as shown in FIGS. 8, 9 and 10, to achieve the same good effect of repairing the panels 20.

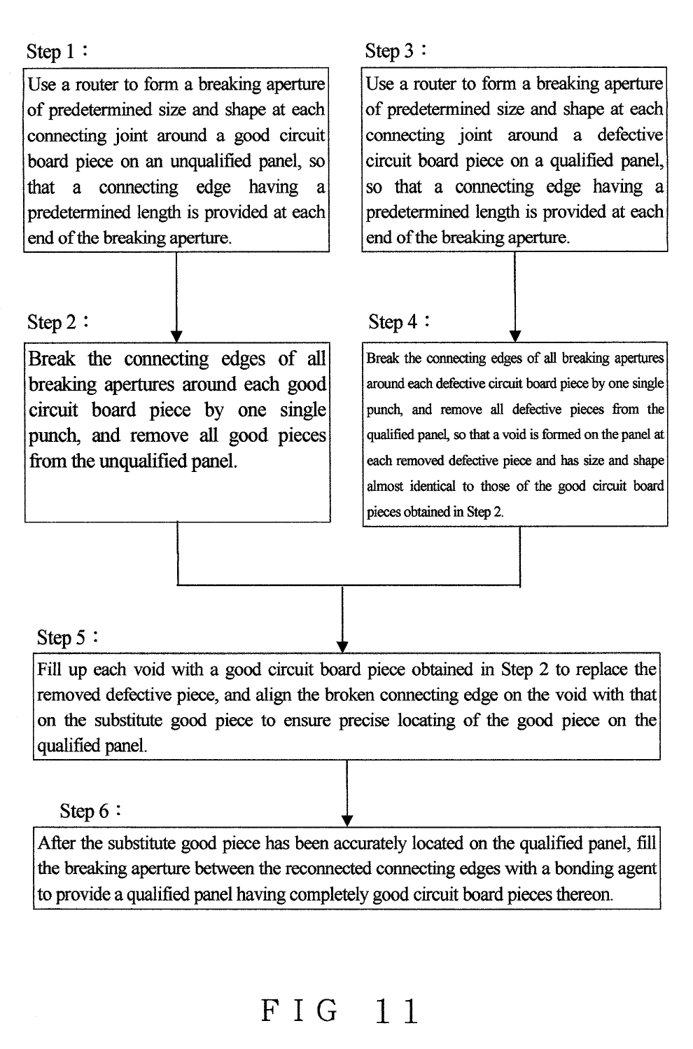

FIG. 11 is a flowchart showing steps included in the method of the present invention. The steps include:

Step 1: Use a router to form a breaking aperture 30 of predetermined size and shape at each connecting joint 13 (23) around a good piece 11 (21) on an unqualified panel 10A (20A), so that a part of the connecting joint 13 (23) about 50 μm in length is left at each end of the breaking aperture 30 to provide a connecting edge 31;

Step 2: Break the connecting edges 31 at two ends of all breaking apertures 30 around one good piece 11 (21) through one single punch to remove the good piece 11 (21) from the unqualified panel 10A (20A), and sequentially remove all other good pieces 11 (21) from the panel 10A (20A) one by one. Locations at which the connecting edges 31 are broken into two parts, that is, breaking lines on the connecting edges 31, may be differently selected as desired;

Step 3: Use the router to form the same breaking aperture 30 at each connecting joint 13 (23) around a defective piece 11A (21A) on a qualified panel 10 (20), so that connecting edges 31 in the above-mentioned suitable length are left at two ends of each breaking aperture 30;

Step 4: Break the connecting edges 31 at two ends of all breaking apertures 30 around one defective piece 11A (21A) through one single punch to remove the defective piece 11A (21A) from the qualified panel 10 (20) to form a void thereat, so that each void has shape and size almost identical to those of the good pieces 11 (21) removed from the unqualified panels 10A (20A) in step 2;

Step 5: Position each removed good piece 11 (21) in one void on the qualified panel 10 (20) to replace the removed defective piece 11A (21A), and correspondingly align the broken connecting edges 31 on the good piece 11 (21) to those left on the void, so that the good piece 11 (21) is accurately located in the void; and

Step 6: After the good piece 11 (21) is accurately located in the void, use a suitable bonding agent to fill the reconnected breaking aperture 30 and thereby bond the good piece 11 (21) to the qualified panel 10 (20), so that all the circuit board pieces on the panel are good ones.

It is noted that the step 1 to the step 2 and the step 3 to the step 4 could be simultaneously conducted.

What is claimed is:

1. A method of removing and replacing a defective piece of printed circuit board formed on a panel, each said printed circuit board piece being connected to said panel and/or to one another at spaced connecting joints provided along a slot profiling said printed circuit board piece, comprising the following steps:
a. Using a router to form a breaking aperture of predetermined size and shape at each said connecting joint around a good piece of said printed circuit board formed on one said panel that is considered as an unqualified panel, so that a part of each said connecting joint is left at each end of each said breaking aperture to provide a connecting edge;
b. Breaking said connecting edges at two ends of all said breaking apertures around one said good printed circuit board piece through one single punch to remove said good piece from said unqualified panel, and sequentially removing all other said goodpieces from said unqualified panel one by one;
c. Using the router to form the same said breaking aperture at each said connecting joint around a defective piece of said printed circuit board formed on one said panel that is considered as a qualified panel, so that connecting edges the same as those formed in step “a” are left at two ends of each said breaking aperture;
d. Breaking said connecting edges at two ends of all said breaking apertures around one said defective printed circuit piece through one single punch to remove said defective piece from said qualified panel and form a void thereat, so that each said void has shape and size almost identical to those of said good pieces removed from said unqualified panels in step “b”;
e. Positioning each said removed good piece into one said void on said qualified panel to replace said removed defective piece, and correspondingly aligning said broken connecting edges on said good printed circuit board piece to those left on said void, so that said good piece is accurately located in said void; and
f. After said good piece having been accurately located in said void, using a predetermined type of bonding agent to fill said breaking aperture that has been reconnected and thereby bond said good piece to said qualified panel, so that all said printed circuit board pieces on said qualified panel are good ones.

2. The method of removing and replacing a defective piece of printed circuit board formed on a panel as claimed in claim 1, wherein each said breaking aperture has a size large enough for filling sufficient amount of said bonding agent therein to create an increased bonding force between said substitute good printed circuit board piece and said qualified panel.

3. The method of removing and replacing a defective piece of printed circuit board formed on a panel as claimed in claim 1, wherein each said connecting edge left at each end of said breaking aperture is about 50 μm in length.

4. The method of removing and replacing a defective piece of printed circuit board formed on a panel as claimed in claim 1, wherein each said connecting edge left at each end of said breaking aperture may be punched broken along a line perpendicular or non-perpendicular to said connecting edge.
